(19) United States
(12) Patent Application Publication
(10) Pub. No.: US 2023/0386796 A1
(43) Pub. Date: Nov. 30, 2023

(54) SUBSTRATE TREATMENT APPARATUS

(71) Applicant: JUSUNG ENGINEERING CO., LTD., Gwangju-si, Gyeonggi-do (KR)

(72) Inventors: Seung Youb SA, Gwangju-si, Gyeonggi-do (KR); Ji Hun LEE, Gwangju-si, Gyeonggi-do (KR); Dae Soo JANG, Gwangju-si, Gyeonggi-do (KR); Bu Il JEON, Gwangju-si, Gyeonggi-do (KR)

(21) Appl. No.: 18/032,518

(22) PCT Filed: Oct. 5, 2021
(86) PCT No.: PCT/KR2021/013582

§ 371 Date: Apr. 18, 2023

(30) Foreign Application Priority Data
Oct. 22, 2020 (KR) 10-2020-0137660
Sep. 29, 2021 (KR) 10-2021-0128561

(51) Int. Cl. H01J 37/32

(52) U.S. Cl. CPC H01J 37/32541; H01J 37/32568; H01J 37/3244; H01J 2237/327

(57) ABSTRACT

The present disclosure relates to a substrate treatment apparatus comprising: a process chamber; a first electrode positioned in the upper part of the process chamber; a second electrode positioned below the first electrode and including a plurality of openings; a plurality of protruding electrodes extending from the first electrode to the plurality of openings of the second electrode; and a substrate support part facing the second electrode and supporting a substrate.

### TECHNICAL FIELD

The present disclosure relates to a substrate processing apparatus which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc.

Such a processing process on a substrate is performed by a substrate processing apparatus. The substrate processing apparatus includes a chamber which provides a reaction space, a supporting unit which supports a substrate, and a gas injection unit which injects a gas toward the supporting unit. The substrate processing apparatus performs a processing process on a substrate by using a source gas and a reactant gas injected by the gas injection unit. In a case where such a processing process is performed, plasma generated between the gas injection unit and the substrate supported by the supporting unit is used.

Here, when plasma having uniform strength is generated over one whole surface of the substrate facing the gas injection unit, the uniformity of the processing process may be secured. However, in the related art, a deviation occurs because the strength of the plasma is partially changed due to a process condition such as the kind of a processing process, the kind of a gas, and a temperature, and due to this, there is a problem where the quality of a substrate, on which the processing process is completed, is reduced.

### DISCLOSURE

### Technical Problem

The present inventive concept is devised to solve the above-described problem and is for providing a substrate processing apparatus which may enhance the uniformity of plasma strength, thereby enhancing the quality of a substrate on which the processing process is completed.

### Technical Solution

To accomplish the above-described objects, the present inventive concept may include the following elements.

A substrate processing apparatus according to the present inventive concept may include: a process chamber providing a reaction space for processing a substrate; a substrate supporting unit supporting the substrate; a first electrode installed in the process chamber, the first electrode being opposite to the substrate and including a plurality of protrusion electrodes protruding toward the substrate; and a second electrode disposed under the first electrode, the second electrode including a plurality of openings into which the plurality of protrusion electrodes are inserted.

In the substrate processing apparatus according to the present inventive concept, a first protrusion electrode disposed in a first region and a second protrusion electrode disposed in a second region outside the first region among the protrusion electrodes may protrude by different lengths.

In the substrate processing apparatus according to the present inventive concept, the first protrusion electrode may protrude toward the substrate by a longer length than the second protrusion electrode.

In the substrate processing apparatus according to the present inventive concept, the second protrusion electrode may protrude toward the substrate by a longer length than the first protrusion electrode.

In the substrate processing apparatus according to the present inventive concept, a second electrode of the first region and a second electrode of the second region in the second electrode may protrude toward the substrate by different lengths.

In the substrate processing apparatus according to the present inventive concept, the second electrode of the first region and the second electrode of the second region in the second electrode may protrude toward the substrate supporting unit by different lengths.

In the substrate processing apparatus according to the present inventive concept, the second electrode of the first region may be apart from the substrate supporting unit by a longer distance than the second electrode of the second region.

In the substrate processing apparatus according to the present inventive concept, the second electrode of the second region may be apart from the substrate supporting unit by a longer distance than the second electrode of the first region.

In the substrate processing apparatus according to the present inventive concept, the first protrusion electrode may include a first injection hole injecting a first gas, the second protrusion electrode may include a second injection hole injecting a second gas, and an area of the first injection hole may differ from an area of the second injection hole.

In the substrate processing apparatus according to the present inventive concept, an area of the first injection hole may be formed to be greater than an area of the second injection hole.

In the substrate processing apparatus according to the present inventive concept, an area of the second injection hole may be formed to be greater than an area of the first injection hole.

In the substrate processing apparatus according to the present inventive concept, the area may be a horizontal cross-sectional area.

In the substrate processing apparatus according to the present inventive concept, at least one of the first protrusion electrode and the second protrusion electrode inserted into the opening may be the same plane as a bottom surface of the second electrode.

In the substrate processing apparatus according to the present inventive concept, the first protrusion electrode and the second protrusion electrode may protrude by the same length.

A substrate processing apparatus according to the present inventive concept may include: a process chamber providing a reaction space for processing a substrate; a substrate supporting unit supporting the substrate; a first injection plate installed in the process chamber, the first injection plate being opposite to the substrate and including a plurality of protrusion paths protruding toward the substrate and injecting a first gas; and a second injection plate disposed under the first injection plate, the second injection plate including a plurality of injection holes into which the protrusion path is inserted and through which a second gas is injected, wherein a first protrusion path disposed in a first region and a second protrusion path disposed in a second region outside the first region among the protrusion paths protrude by different lengths.

In the substrate processing apparatus according to the present inventive concept, the first protrusion path may protrude toward the substrate by a longer length than the second protrusion path.

In the substrate processing apparatus according to the present inventive concept, the second protrusion path may protrude toward the substrate by a longer length than the first protrusion path.

### Advantageous Effect

According to the present inventive concept, the following effects may be realized.

The present inventive concept may be implemented to control the strength of plasma for each region, and thus, may enhance the uniformity of plasma strength over one whole surface of a substrate. Accordingly, the present inventive concept may enhance the quality of a substrate on which a processing process is completed.

The present inventive concept may be implemented to control a pressure and a flow rate of a gas for each region, and thus, may enhance the uniformity of a gas injected onto one whole surface of a substrate. Accordingly, the present inventive concept may enhance the quality of a substrate on which a processing process is completed.

### DESCRIPTION OF DRAWINGS

FIG. 1 is a schematic side cross-sectional view of a substrate processing apparatus according to the present inventive concept.

FIG. 2 is a schematic side cross-sectional view illustrating the enlargement of a portion A of FIG. 1, in a substrate processing apparatus according to the present inventive concept.

FIG. 3 is a schematic bottom view illustrating a bottom surface of a first electrode in a substrate processing apparatus according to the present inventive concept.

FIGS. 4 to 9 are schematic side cross-sectional views illustrating the enlargement of a first electrode, a second electrode, and protrusion electrodes in a first region and a second region in a substrate processing apparatus according to the present inventive concept.

FIG. 10 is a schematic side cross-sectional view of a substrate processing apparatus according to a modified embodiment of the present inventive concept.

FIG. 11 is a schematic side cross-sectional view illustrating the enlargement of a portion B of FIG. 10, in a substrate processing apparatus according to a modified embodiment of the present inventive concept.

FIG. 12 is a schematic bottom view illustrating a bottom surface of a first injection plate in a substrate processing apparatus according to a modified embodiment of the present inventive concept.

FIGS. 13 and 14 are schematic side cross-sectional views illustrating the enlargement of a first injection plate, a second injection plate, and protrusion paths in a first region and a second region in a substrate processing apparatus according to a modified embodiment of the present inventive concept.

### MODE FOR INVENTION

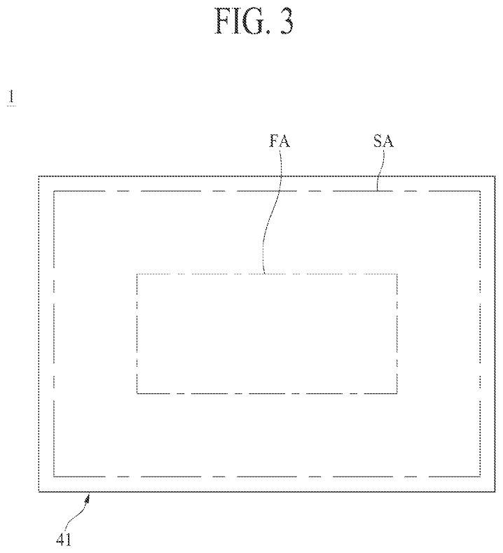

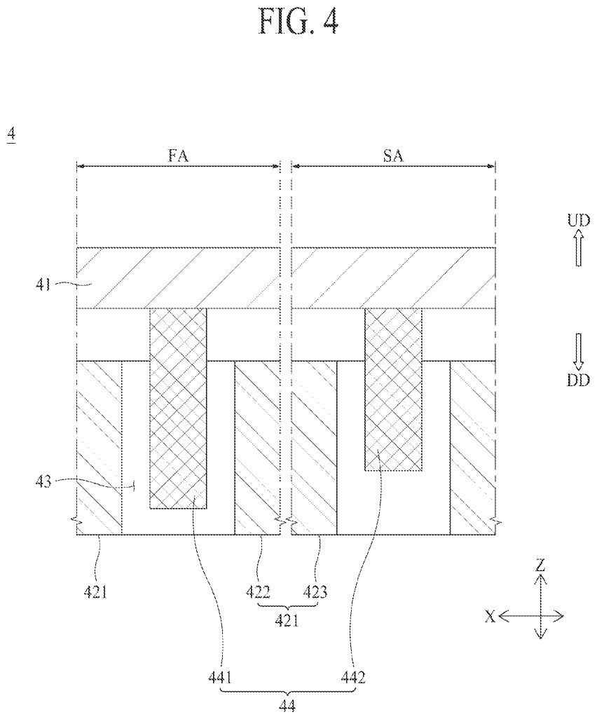

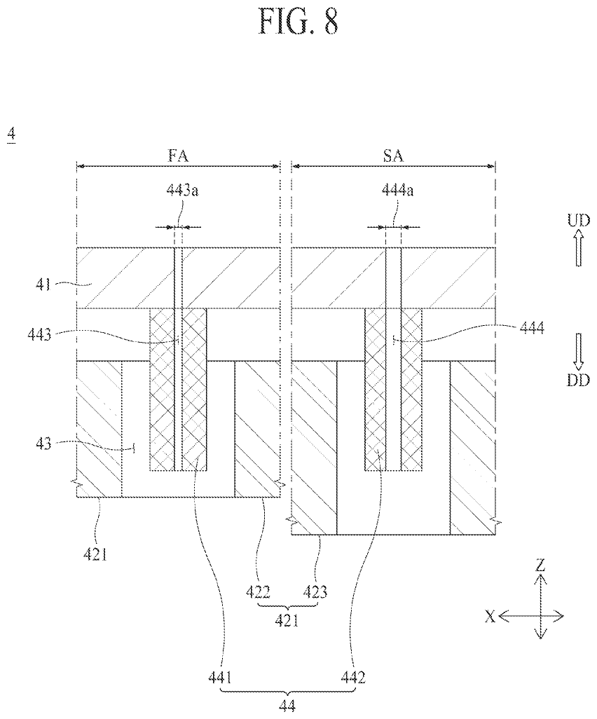

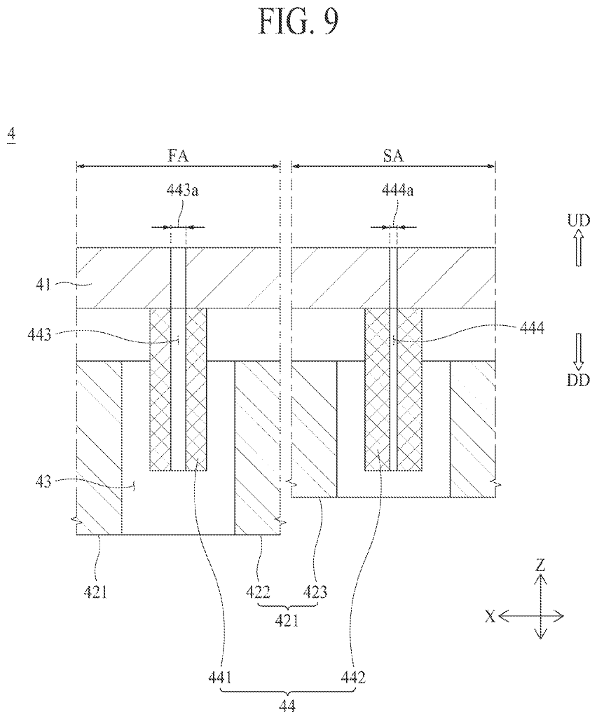

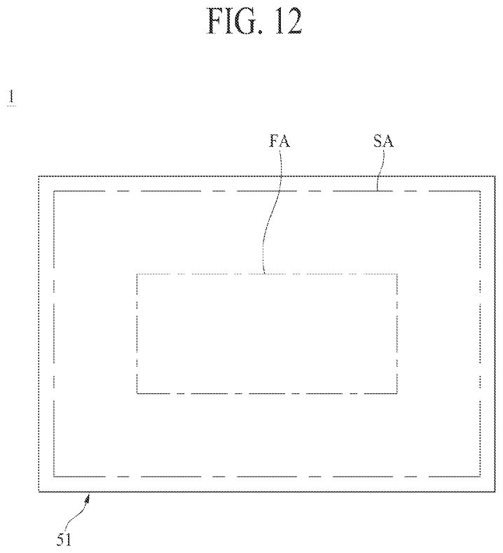

Hereinafter, an embodiment of a substrate processing apparatus according to the present inventive concept will be described in detail with reference to the accompanying drawings. In FIG. 3, protrusion electrodes coupled to a bottom surface of a first electrode is omitted. In FIGS. 4 to 9, 13, and 14, a one-dot-dashed line is an omitted line. In FIG. 12, protrusion paths coupled to a bottom surface of a first injection plate are omitted.

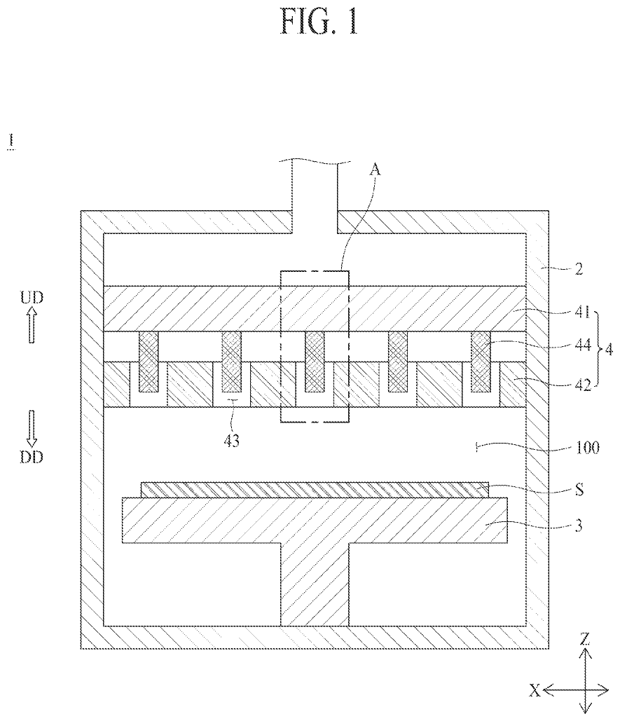

Referring to FIG. 1, a substrate processing apparatus 1 according to the present inventive concept performs a processing process on a substrate S. The substrate S may be a silicon substrate, a glass substrate, a metal substrate, or the like. The substrate processing apparatus 1 according to the present inventive concept may perform a deposition process of depositing a thin film on the substrate S, an etching process of removing a portion of the thin film deposited on the substrate S, etc. For example, the substrate processing apparatus 1 according to the present inventive concept may perform a deposition process such as a chemical vapor deposition (CVD) process and an atomic layer deposition (ALD) process. Hereinafter, an embodiment where the substrate processing apparatus 1 according to the present inventive concept performs the deposition process will be described mainly, and based thereon, it is obvious to those skilled in the art that an embodiment is devised where the substrate processing apparatus 1 according to the present inventive concept performs another processing process such as the etching process.

The substrate processing apparatus 1 according to the present inventive concept may include a process chamber 2, a substrate supporting unit 3, and an electrode unit 4.

<Process Chamber>

Referring to FIG. 1, the process chamber 2 provides a reaction space 100. In the reaction space 100, a processing process such as a deposition process and an etching process may be performed on the substrate S. The substrate supporting unit 3 and the electrode unit 4 may be disposed in the process chamber 2.

<Supporting Unit>

Referring to FIG. 1, the substrate supporting unit 3 supports the substrate S. The substrate supporting unit 3 may support one substrate S, or may support a plurality of substrates S. The substrate supporting unit 3 may rotate about a supporting shaft (not shown) in the process chamber 2.

<Electrode Unit>

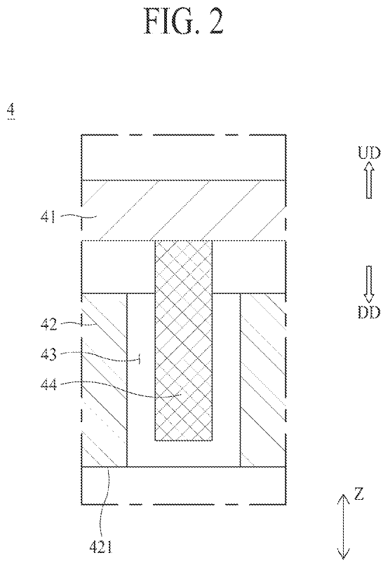

Referring to FIGS. 1 and 2, the electrode unit 4 is disposed to be opposite to the substrate supporting unit 3. The electrode unit 4 may be disposed at an upper portion of the process chamber 2. The reaction space 100 may be disposed between the electrode unit 4 and the substrate supporting unit 3. The electrode unit 4 may inject a gas toward the substrate supporting unit 3. In this case, the electrode unit 4 may function as a gas injection unit. The gas is used in a processing process on the substrate S, and for example, may be a source gas and a reactant gas. In this case, the electrode unit 4 may be connected to a gas supply unit (not shown) which supplies a gas. The electrode unit 4 may generate plasma. Accordingly, the substrate processing apparatus 1 according to the present inventive concept may perform a processing process on the substrate S by using a gas injected by the electrode unit 4 and plasma generated by the electrode unit 4. In this case, a portion of the electrode unit 4 may be grounded, and another portion of the electrode unit 4 may be electrically connected to a power unit (not shown). The power unit may apply a radio frequency (RF) power.

The electrode unit 4 may include a first electrode 41, a second electrode 42, an opening 43, and a protrusion electrode 44.

The first electrode 41 may be installed in the process chamber 2 and may be opposite to the substrate S. The first electrode 41 may be disposed at the upper portion of the process chamber 2. The first electrode 41 may be disposed on the second electrode 42 at the upper portion of the process chamber 2. The first electrode 41 may be disposed upward (an UD arrow direction) apart from the second electrode 42. The first electrode 41 may include a plurality of protrusion electrodes 44.

The second electrode 42 may be disposed under the first electrode 41. The second electrode 42 may be opposite to the substrate supporting unit 3. The second electrode 42 may be disposed upward (the UD arrow direction) apart from the substrate supporting unit 3 and may be disposed downward (a DD arrow direction) apart from the first electrode 41. The second electrode 42 may be disposed so that a bottom surface 421 thereof faces the substrate supporting unit 3 and a top surface thereof faces the first electrode 41. A bottom surface of the first electrode 41 and a top surface of the second electrode 42 may be disposed apart from each other with respect to a vertical direction (a Z-axis direction). A plurality of openings 43 into which the protrusion electrode 44 is inserted may be formed in the second electrode 42.

The RF power may be applied to one of the second electrode 42 and the first electrode 41, and the other may be grounded. For example, the RF power may be applied to the second electrode 42, and the first electrode 41 may be grounded. The second electrode 42 may be grounded, and the RF power may be applied to the first electrode 41.

Referring to FIGS. 1 and 2, the opening 43 may be formed to pass through the second electrode 42. The opening 43 may pass through the top surface and the bottom surface 421 of the second electrode 42. The opening 43 may be formed in a wholly cylindrical shape, but is not limited thereto and may also be formed in another shape such as a rectangular parallelepiped shape. A plurality of openings 43 may be formed in the second electrode 42. In this case, the openings 43 may be disposed at positions apart from one another. The openings 43 may be disposed apart from one another by the same interval.

Referring to FIGS. 1 and 2, the protrusion electrode 44 protrudes toward the substrate S. The protrusion electrode 44 may extend from the first electrode 41 and may extend toward the opening 43 formed in the second electrode 42. The protrusion electrode 44 may protrude downward (the DD arrow direction) from the first electrode 41. The protrusion electrode 44 may protrude from a portion, disposed on the opening 43, of the bottom surface of the first electrode 41. That is, the protrusion electrode 44 may be disposed at a position corresponding to the opening 43. The protrusion electrode 44 may be coupled to the bottom surface of the first electrode 41. When the first electrode 41 is grounded, the protrusion electrode 44 may be grounded through the first electrode 41. When the RF power is applied to the first electrode 41, the RF power may be applied to the protrusion electrode 44 through the first electrode 41. Accordingly, discharging may be performed by an electrical field applied between the protrusion electrode 44 and the second electrode 42, and thus, plasma may be generated. The plasma may be generated between the bottom surface 421 of the second electrode 42 and the substrate supporting unit 3. Plasma may be generated in the opening 43.

The electrode unit 4 may include a plurality of protrusion electrodes 44. In this case, the second electrode 42 may include a plurality of openings 43. The protrusion electrodes 44 may be disposed at positions apart from one another. The protrusion electrodes 44 may protrude from portions, disposed on the openings 43, of the bottom surface of the first electrode 41. That is, the protrusion electrodes 44 may be respectively disposed at positions corresponding to the openings 43.

The protrusion electrodes 44 may be disposed to be opposite to the substrate S supported by the substrate supporting unit 3. In this case, the protrusion electrodes 44 may be opposite to different portions of the substrate S. The bottom surface 421 of the second electrode 42 may be opposite to the substrate S supported by the substrate supporting unit 3. In this case, one surface of the substrate S may be disposed to be opposite to each of the protrusion electrodes 44 and the bottom surface 421 of the second electrode 42. The one surface of the substrate S may correspond to a surface where the processing process is performed.

Here, in a case where the protrusion electrodes 44 protrude from the first electrode 41 by the same length, a deviation may occur because the strength of plasma is partially changed due to a process condition such as the kind of the processing process, the kind of a gas, and a temperature. In order to compensate for such a difference, in the substrate processing apparatus 1 according to the present inventive concept, the protrusion electrodes 44 may be implemented as follows.

Referring to FIGS. 1 to 4, a first protrusion electrode 441 disposed in a first region FA and a second protrusion electrode 442 disposed in a second region SA differing from the first region FA among the protrusion electrodes 44 may protrude by different lengths. That is, each of the first protrusion electrode 441 and the second protrusion electrode 442 may be implemented to have different lengths which protrude toward the substrate S.

Therefore, in the substrate processing apparatus 1 according to the present inventive concept, in a case where a plasma strength difference between the first region FA and the second region SA occurs due to a process condition or the like, the plasma strength difference occurring between the first region FA and the second region SA may be compensated for by using a difference between a length of the first protrusion electrode 441 and a length of the second protrusion electrode 442.

For example, when a length of the first protrusion electrode 441 is the same as that of the second protrusion electrode 442, in a case where the strength of plasma generated by the second region SA is reduced compared to the first region FA due to a process condition or the like, a process environment may be implemented where plasma, having strength which is stronger in the second region SA than the first region FA, is generated. To this end, as illustrated in FIG. 4, the first protrusion electrode 441 may protrude toward the substrate S by a longer length than the second protrusion electrode 442. Therefore, the second protrusion electrode 442 may protrude toward the substrate S by a shorter length than the first protrusion electrode 441. Therefore, the strength of plasma generated by using the second protrusion electrode 442 in the second region SA may increase, and thus, a plasma strength deviation between the second region SA and the first region FA may decrease. In this case, a portion corresponding to an edge of the substrate S may be disposed in the second region SA. A portion corresponding to a center of the substrate S may be disposed in the first region FA. The portion corresponding to the edge of the substrate S may be disposed to surround the portion corresponding to the center of the substrate S. The portion corresponding to the center of the substrate S may be disposed inward from the portion corresponding to the edge of the substrate S.

For example, when a length of the first protrusion electrode 441 is the same as that of the second protrusion electrode 442, in a case where the strength of plasma generated by the first region FA is reduced compared to the second region SA due to a process condition or the like, a process environment may be implemented where plasma, having strength which is stronger in the first region FA than the second region SA, is generated. To this end, the second protrusion electrode 442 may protrude toward the substrate S by a longer length than the first protrusion electrode 441. Therefore, the first protrusion electrode 441 may protrude toward the substrate S by a shorter length than the second protrusion electrode 442. Therefore, the strength of plasma generated by using the first protrusion electrode 441 in the first region FA may increase, and thus, a plasma strength deviation between the first region FA and the second region SA may decrease.

As described above, the substrate processing apparatus 1 according to the present inventive concept is implemented to control the strength of plasma for each region by using a difference between a length of the first protrusion electrode 441 and a length of the second protrusion electrode 442. Therefore, the substrate processing apparatus 1 according to the present inventive concept may enhance the uniformity of plasma strength in one whole surface of the substrate S facing the electrode unit 4, thereby enhancing the quality of a substrate on which the processing process is completed.

The second region SA may be disposed outside the first region FA. In this case, as illustrated in FIG. 3, the second region SA may be disposed outside the first region FA to surround the first region FA. Although not shown, when each of the second region SA and the first region FA is a region where a plasma strength difference occurs due to a process condition or the like, the second region SA and the first region FA may be implemented as a type and arrangement which differ from the illustration of FIG. 3. Hereinabove, it has been described that lengths of the protrusion electrodes 44 differ in two regions FA and SA, but the present inventive concept is not limited thereto and the lengths of the protrusion electrodes 44 may be differently implemented in three or more regions. Also, in FIG. 3, it is illustrated that the first electrode 41 has a tetragonal shape, but the present inventive concept is not limited thereto and the first electrode 41 may be formed in various shapes such as a tetragonal or more-shaped polygonal shape and a circular shape.

Referring to FIG. 4, the first protrusion electrode 441 and the second protrusion electrode 442 may be inserted into the opening 43 and may be disposed inward from the second electrode 42. In this case, with respect to the vertical direction (the Z-axis direction), each of the first protrusion electrode 441 and the second protrusion electrode 442 may protrude toward the substrate S by a longer length than a length by which the first electrode 41 is apart from the second electrode 42.

One of the first protrusion electrode 441 and the second protrusion electrode 442 inserted into the opening 43 may be the same plane as the bottom surface 421 of the second electrode 42. In this case, a bottom surface of the first protrusion electrode 441 or a bottom surface of the second protrusion electrode 442 may be disposed at the same height as the bottom surface 421 of the second electrode 42. A bottom surface of a protrusion electrode, having a longer length, of the first protrusion electrode 441 and the second protrusion electrode 442 may be disposed at the same height as the bottom surface 421 of the second electrode 42. A bottom surface of a protrusion electrode, having a shorter length, of the first protrusion electrode 441 and the second protrusion electrode 442 may be disposed at a higher height than the bottom surface 421 of the second electrode 42, and thus, may be disposed inward from the second electrode 42.

Referring to FIG. 4, when the first protrusion electrode 441 and the second protrusion electrode 442 protrude by different lengths, the bottom surface 421 of the second electrode 42 may be formed to be flat. That is, all of the bottom surface 421 of the second electrode 42 may be disposed at the same height. Accordingly, in controlling the strength of plasma for each region by using a difference between a length of the first protrusion electrode 441 and a length of the second protrusion electrode 442, the bottom surface 421 of the second electrode 42 may be implemented not to be affected.

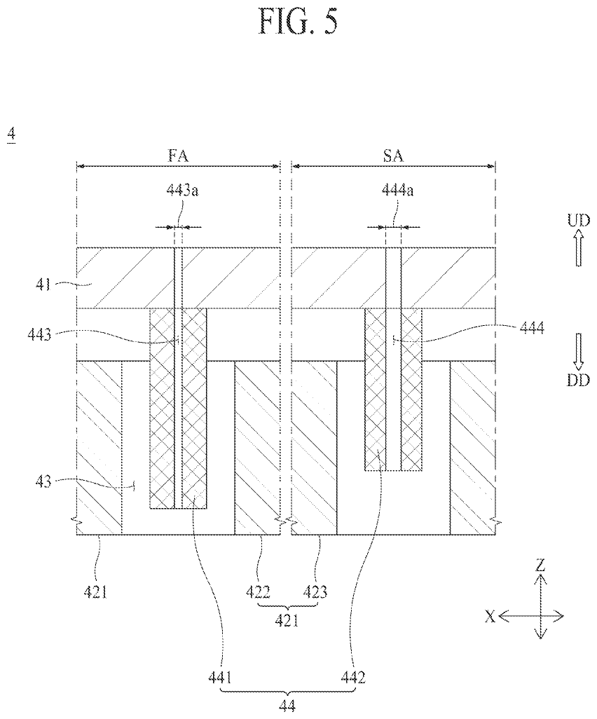

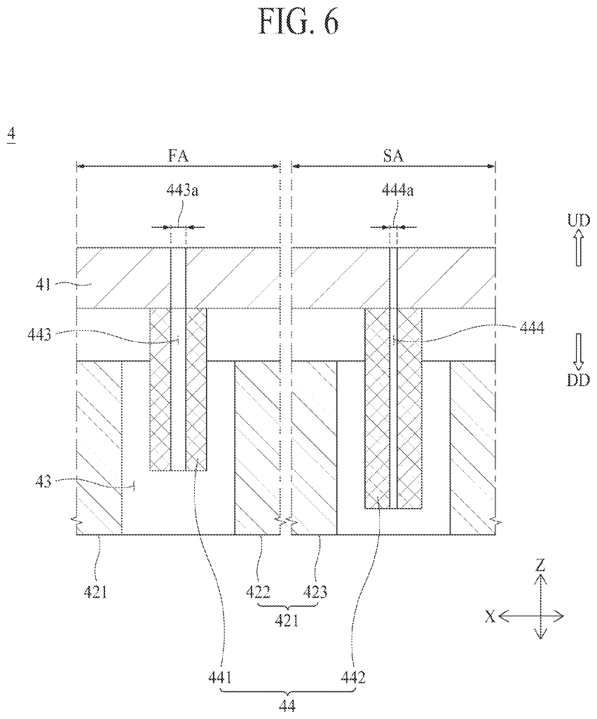

Referring to FIGS. 5 and 6, the first protrusion electrode 441 may include a first injection hole 443 for injecting a first gas. The first injection hole 443 may be formed to pass through the first protrusion electrode 441. The first injection hole 443 may be formed to pass through the first protrusion electrode 441 and the first electrode 41. In this case, the first gas may be injected into a space disposed on the first electrode 41, and then, may be injected toward the substrate supporting unit 3 through the first injection hole 443.

Referring to FIGS. 5 and 6, the second protrusion electrode 442 may include a second injection hole 444 for injecting a second gas. The second injection hole 444 may be formed to pass through the second protrusion electrode 442. The second injection hole 444 may be formed to pass through the second protrusion electrode 442 and the first electrode 41. In this case, the second gas may be injected into a space disposed on the first electrode 41, and then, may be injected toward the substrate supporting unit 3 through the second injection hole 444. The second gas and the first gas may be the same gas. The second gas and the first gas may be different gases. In this case, the first injection hole 443 and the second injection hole 444 may be respectively connected to gas flow paths which are spatially apart from each other.

An area 443a of the first injection hole 443 and an area 444a of the second injection hole 444 may be differently formed. Therefore, a flow rate per unit time of a gas injected into the second region SA through the second injection hole 444 and a flow rate per unit time of a gas injected into the first region FA through the first injection hole 443 may be differently implemented. Therefore, the substrate processing apparatus 1 according to the present inventive concept is implemented to control a flow rate per unit time of a gas injected into each region by using an area difference between the second injection hole 444 and the first injection hole 443. Accordingly, when the second injection hole 444 and the first injection hole 443 are formed to have the same area, in a case where a deviation of a process processing rate of the substrate S occurs partially due to a process condition in a process of performing the processing process, the substrate processing apparatus 1 according to the present inventive concept may compensate for a deviation of a process processing rate of the substrate S by using an area difference between the second injection hole 444 and the first injection hole 443, thereby enhancing the uniformity of a process processing rate of the substrate S. When the processing process is a deposition process, a process processing rate of the substrate S may correspond to a thickness of a thin film deposited on the substrate S.

For example, when the area 443a of the first injection hole 443 is the same as the area 444a of the second injection hole 444, in a case where a process processing rate of the substrate S in the second region SA is reduced compared to the first region FA, a process environment where a gas is injected at a flow rate per unit time which is higher in the second region SA than the first region FA may be implemented. To this end, as illustrated in FIG. 5, the area 444a of the second injection hole 444 may be formed to be greater than the area 443a of the first injection hole 443. Therefore, a flow rate per unit time of an injected gas in the second region SA may increase by using the second injection hole 444, and thus, a process processing rate of the substrate S in the second region SA may increase. Accordingly, a deviation of a process processing rate between the first region FA and the second region SA may decrease. In this case, the second protrusion electrode 442 may protrude toward the substrate S to be shorter than the first protrusion electrode 441.

For example, when the area 443a of the first injection hole 443 is the same as the area 444a of the second injection hole 444, in a case where a process processing rate of the substrate S in the first region FA is reduced compared to the second region SA, a process environment where a gas is injected at a flow rate per unit time which is higher in the first region FA than the second region SA may be implemented. To this end, as illustrated in FIG. 6, the area 443a of the first injection hole 443 may be formed to be greater than the area 444a of the second injection hole 444. Therefore, a flow rate per unit time of an injected gas in the first region FA may increase by using the first injection hole 443, and thus, a process processing rate of the substrate S in the first region FA may increase. Accordingly, a deviation of a process processing rate between the first region FA and the second region SA may decrease. In this case, the first protrusion electrode 441 may protrude toward the substrate S to be shorter than the second protrusion electrode 442.

Moreover, the area 444a of the second injection hole 444 and the area 443a of the first injection hole 443 may each be a horizontal cross-sectional area. A horizontal cross-sectional area may denote a size of an area with respect to a horizontal direction (an X-axis direction) vertical to the vertical direction (the Z-axis direction).

Moreover, a plurality of first protrusion electrodes 441 may be disposed in the first region FA. In this case, the first protrusion electrodes 441 may protrude by different lengths toward the substrate S. A plurality of second protrusion electrodes 442 may be disposed in the second region SA. In this case, the second protrusion electrodes 442 may protrude by the same length toward the substrate S.

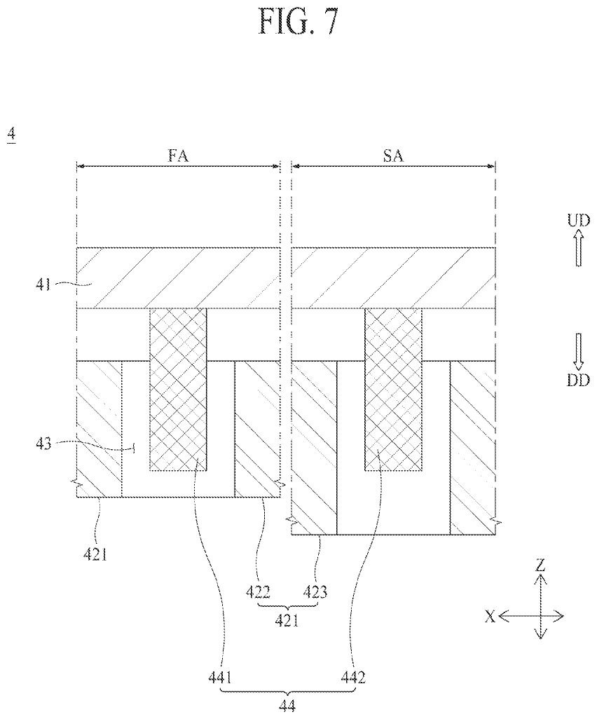

Referring to FIGS. 1 and 7, the substrate processing apparatus 1 according to the present inventive concept may be implemented so that a distance between the second electrode 42 and the substrate supporting unit 3 differs for each region, and thus, may compensate for a deviation which occurs because the strength of plasma is partially changed due to a process condition or the like. In this case, the second electrode 42 may be implemented as follows.

A second electrode 422 of the first region FA in the second electrode 42 and a second electrode 423 of the second region SA in the second electrodes 42 may be apart from the substrate supporting unit 3 by different lengths. In this case, a first distance by which the second electrode 422 of the first region FA is apart from the substrate supporting unit 3 and a second distance by which the second electrode 423 of the second region SA is apart from the substrate supporting unit 3 may be differently implemented. The first distance may denote a distance by which a bottom surface of the second electrode 422 of the first region FA is apart from a top surface of the substrate supporting unit 3 with respect to the vertical direction (the Z-axis direction). The second distance may denote a distance by which a bottom surface of the second electrode 423 of the second region SA is apart from the top surface of the substrate supporting unit 3 with respect to the vertical direction (the Z-axis direction).

Therefore, when a plasma strength difference between the first region FA and the second region SA occurs due to a process condition or the like, the substrate processing apparatus 1 according to the present inventive concept may compensate for a plasma strength difference occurring between the first region FA and the second region SA by using a difference between the first distance and the second distance.

For example, when the first distance is the same as the second distance, in a case where the strength of plasma generated in the second region SA is reduced compared to the first region FA due to a process condition or the like, a process environment may be implemented where plasma having strength which is stronger in the second region SA than the first region FA is generated. To this end, as illustrated in FIG. 7, the second electrode 422 of the first region FA may be apart from the substrate supporting unit 3 by a longer distance than the second electrode 423 of the second region SA. Therefore, the second electrode 423 of the second region SA may be apart from the substrate supporting unit 3 by a shorter distance than the second electrode 422 of the first region FA. In this case, the second electrode 423 of the second region SA may more protrude toward the substrate S than the second electrode 422 of the first region FA. Accordingly, the strength of plasma generated by using a portion where the second electrode 423 of the second region SA is formed may increase in the second region SA, and thus, a plasma strength deviation between the second region SA and the first region FA may decrease.

For example, when the first distance is the same as the second distance, in a case where the strength of plasma generated in the first region FA is reduced compared to the second region SA due to a process condition or the like, a process environment may be implemented where plasma having strength which is stronger in the first region FA than the second region SA is generated. To this end, the second electrode 423 of the second region SA may be apart from the substrate supporting unit 3 by a longer distance than the second electrode 422 of the first region FA. Therefore, the second electrode 422 of the first region FA may be apart from the substrate supporting unit 3 by a shorter distance than the second electrode 423 of the second region SA. In this case, the second electrode 422 of the first region FA may be formed to more protrude toward the substrate S than the second electrode 423 of the second region SA. Accordingly, the strength of plasma generated by using a portion where the second electrode 422 of the first region FA is formed may increase in the first region FA, and thus, a plasma strength deviation between the second region SA and the first region FA may decrease.

As described above, the substrate processing apparatus 1 according to the present inventive concept is implemented to control the strength of plasma for each region by using a difference between the first distance and the second distance. Therefore, the substrate processing apparatus 1 according to the present inventive concept may enhance the uniformity of plasma strength in one whole surface of the substrate S facing the electrode unit 4, thereby enhancing the quality of a substrate on which the processing process is completed. Also, the substrate processing apparatus 1 according to the present inventive concept may be implemented so that the second electrode 422 of the first region FA and the second electrode 423 of the second region SA protrude toward the substrate S by different lengths.

Referring to FIGS. 1, 3, and 7, the second region SA may be disposed outside the first region FA. In this case, as illustrated in FIG. 3, the second region SA may be disposed outside the first region FA to surround the first region FA. Although not shown, when each of the second region SA and the first region FA is a region where a plasma strength difference occurs due to a process condition or the like, the second region SA and the first region FA may be implemented as a type and arrangement which differ from the illustration of FIG. 3. Hereinabove, it has been described that a distance between the second electrode 42 and the substrate supporting unit 3 differs in the two regions FA and SA, but the present inventive concept is not limited thereto and the distance between the second electrode 42 and the substrate supporting unit 3 may be differently implemented in three or more regions. Also, in FIG. 3, it is illustrated that the first electrode 41 has a tetragonal shape, but the present inventive concept is not limited thereto and the first electrode 41 may be formed in various shapes such as a tetragonal or more-shaped polygonal shape and a circular shape.

Referring to FIGS. 1 and 7, the second electrode 422 of the first region FA and the second electrode 423 of the second region SA are apart from the substrate supporting unit 3 by different distances, the first protrusion electrode 441 and the second protrusion electrode 442 may protrude by the same length. That is, the bottom surface of the first protrusion electrode 441 and the bottom surface of the second protrusion electrode 442 may be disposed at the same height. Accordingly, in controlling the strength of plasma for each region by using a difference between the first distance and the second distance, a length of each of the first protrusion electrode 441 and the second protrusion electrode 442 may be implemented not to be affected. In this case, the first protrusion electrode 441 and the second protrusion electrode 442 may be inserted into the opening 43 and may be disposed inward from the second electrode 42. The first protrusion electrode 441 and the second protrusion electrode 442 inserted into the opening 43 may be the same plane as the bottom surface 421 of the second electrode 42.

Referring to FIGS. 1, 8, and 9, the first protrusion electrode 441 may include the first injection hole 443. The second protrusion electrode 442 may include the second injection hole 444. The first injection hole 443 and the second injection hole 444 are approximately the same as the description of the substrate processing apparatus 1 according to the present inventive concept described above, and thus, a detailed description is omitted.

Moreover, a plurality of first protrusion electrodes 441 may be disposed in the first region FA. In this case, the first protrusion electrodes 441 may protrude toward the substrate S by the same length. A plurality of second protrusion electrodes 442 may be disposed in the second region SA. In this case, the second protrusion electrodes 442 may protrude toward the substrate S by the same length.

Although not shown, in the substrate processing apparatus 1 according to the present inventive concept, a length of the first protrusion electrode 441 and a length of the second protrusion electrode 442 may be differently implemented, and the first distance and the second distance may be differently implemented. In a case where it is required to more increase the strength of plasma in the second region SA than the first region FA, the second protrusion electrode 442 may be formed to be shorter than the first protrusion electrode 441, and the second distance may be formed to be shorter than the first distance. In a case where it is required to more increase the strength of plasma in the first region FA than the second region SA, the first protrusion electrode 441 may be formed to be shorter than the second protrusion electrode 442, and the first distance may be formed to be shorter than the second distance. Also, a protrusion electrode having a longer length among the first protrusion electrode 441 and the second protrusion electrode 442 may be implemented not to protrude downward (the DD arrow direction) from the bottom surface 421 of the second electrode 42.

Although not shown, the substrate processing apparatus 1 according to the present inventive concept may be implemented so that the first protrusion electrode 441 disposed in the first region FA and the second protrusion electrode 442 disposed in the second region SA protrude by different lengths and the second electrode 422 of the first region FA and the second electrode 423 of the second region SA protrude toward the substrate S by different lengths.

For example, the first protrusion electrode 441 may protrude by a longer length than the second protrusion electrode 442, and the second electrode 422 of the first region FA may protrude by a longer length than the second electrode 423 of the second region SA. For example, the first protrusion electrode 441 may protrude by a longer length than the second protrusion electrode 442, and the second electrode 423 of the second region SA may protrude by a longer length than the second electrode 422 of the first region FA.

For example, the second protrusion electrode 442 may protrude by a longer length than the first protrusion electrode 441, and the second electrode 422 of the first region FA may protrude by a longer length than the second electrode 423 of the second region SA. For example, the second protrusion electrode 442 may protrude by a longer length than the first protrusion electrode 441, and the second electrode 423 of the second region SA may protrude by a longer length than the second electrode 422 of the first region FA.

As described above, the substrate processing apparatus 1 according to the present inventive concept may be implemented so that the first protrusion electrode 441 disposed in the first region FA and the second protrusion electrode 442 disposed in the second region SA protrude by different lengths and the second electrode 422 of the first region FA and the second electrode 423 of the second region SA protrude toward the substrate S by different lengths, and thus, may enhance various characteristics of plasma control for each region and may enhance the easiness and accuracy of plasma control for each region.

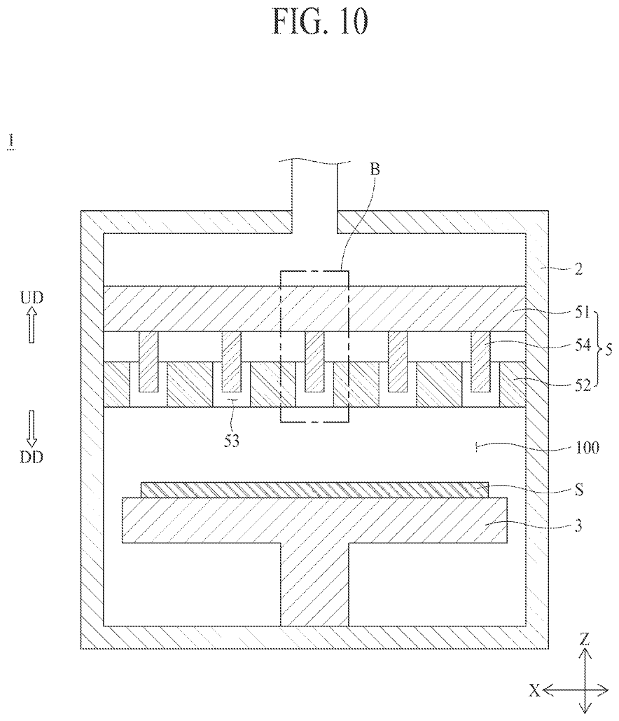

Referring to FIG. 10, a substrate processing apparatus 1 according to a modified embodiment of the present inventive concept performs a processing process on a substrate S. The substrate processing apparatus 1 according to a modified embodiment of the present inventive concept may include a process chamber 2, a substrate supporting unit 3, and a gas injection unit 5. The process chamber 2 and the substrate supporting unit 3 are approximately the same as the description of the substrate processing apparatus 1 according to the present inventive concept described above, and thus, a detailed description is omitted.

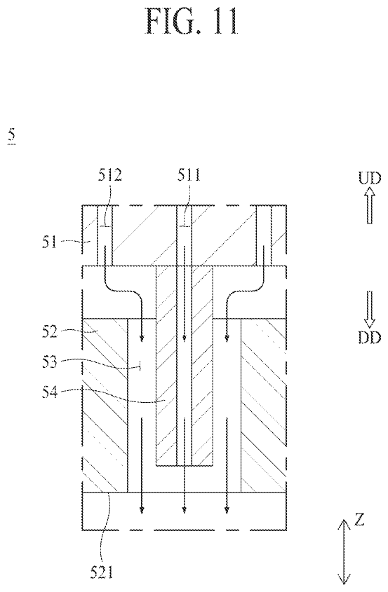

Referring to FIGS. 10 and 11, the gas injection unit 5 is disposed to be opposite to the substrate supporting unit 3. The gas injection unit 5 may be disposed at an upper portion of the process chamber 2. The reaction space 100 may be disposed between the gas injection unit 5 and the substrate supporting unit 3. The gas injection unit 5 may inject a gas toward the substrate supporting unit 3. The gas is used in a processing process on the substrate S, and for example, may be a source gas and a reactant gas. In this case, the gas injection unit 5 may be connected to a gas supply unit (not shown) which supplies a gas.

The gas injection unit 5 may include a first injection plate 51, a second injection plate 52, and a protrusion path 54.

The first injection plate 51 may be installed in the process chamber 2 and may be opposite to the substrate S. The first injection plate 51 may be disposed at the upper portion of the process chamber 2. The first injection plate 51 may be disposed on the second injection plate 52 at the upper portion of the process chamber 2. The first injection plate 51 may be disposed upward (an UD arrow direction) apart from the second injection plate 52. The first injection plate 51 may include a plurality of protrusion paths 54 through which a first gas is injected.

The second injection plate 52 may be disposed under the first injection plate 51. The second injection plate 52 may be opposite to the substrate supporting unit 3. The second injection plate 52 may be disposed upward (the UD arrow direction) apart from the substrate supporting unit 3 and may be disposed downward (a DD arrow direction) apart from the first injection plate 51. The second injection plate 52 may be disposed so that a bottom surface 421 thereof faces the substrate supporting unit 3 and a top surface thereof faces the first injection plate 51. A bottom surface of the first injection plate 51 and a top surface of the second injection plate 52 may be disposed apart from each other with respect to a vertical direction (a Z-axis direction). A plurality of injection holes 53 may be formed in the second injection plate 52.

Referring to FIGS. 10 and 11, the injection hole 53 injects a second gas. The injection hole 53 may be formed to pass through the second injection plate 52. The injection hole 53 may pass through a top surface and a bottom surface 521 of the second injection plate 52. The second gas may be supplied to a region between the first injection plate 51 and the second injection plate 52 through a first connection hole 511 formed in the first injection plate 51, and then, may be injected toward the substrate S through the injection hole 53. The first connection hole 511 may be formed to pass through the first injection plate 51. The first connection hole 511 may be disposed at a position corresponding to a portion of the second injection plate 52 where the injection hole 53 is not formed. The injection hole 53 may be formed in a wholly cylindrical shape, but is not limited thereto and may also be formed in another shape such as a rectangular parallelepiped shape. A plurality of injection holes 53 may be formed in the second injection plate 52. In this case, the injection holes 53 may be disposed at positions apart from one another. The injection holes 53 may be disposed apart from one another by the same interval.

Referring to FIGS. 10 and 11, the protrusion path 54 injects the first gas. The first gas and the second gas may be different gases. For example, when the first gas is a source gas, the second gas may be a reactant gas. When the first gas is a reactant gas, the second gas may be a source gas.

The protrusion path 54 may protrude toward the substrate S. The protrusion path 54 may extend from the first injection plate 51 and may extend toward the injection hole 53 formed in the second injection plate 52. The protrusion path 54 may be inserted into the injection hole 53. The protrusion path 54 may protrude downward (the DD arrow direction) from the first injection plate 51. The protrusion path 54 may protrude from a portion, disposed on the injection hole 53, of a bottom surface of the first injection plate 51. That is, the protrusion path 54 may be disposed at a position corresponding to the injection hole 53. The protrusion path 54 may be coupled to the bottom surface of the first injection plate 51.

The gas injection unit 5 may include a plurality of protrusion paths 54. In this case, the second injection plate 52 may include a plurality of injection holes 53. The protrusion paths 54 may be disposed at positions apart from one another. The protrusion paths 54 may protrude from portions, disposed on the injection holes 53, of the bottom surface of the first injection plate 51. That is, the protrusion paths 54 may be respectively disposed at positions corresponding to the injection holes 53.

The protrusion paths 54 may be disposed to be opposite to the substrate S supported by the substrate supporting unit 3. In this case, the protrusion paths 54 may be opposite to different portions of the substrate S. The bottom surface 521 of the second injection plate 52 may be opposite to the substrate S supported by the substrate supporting unit 3. In this case, one surface of the substrate S may be disposed to be opposite to each of the protrusion paths 54 and the bottom surface 521 of the second injection plate 52. The one surface of the substrate S may correspond to a surface where the processing process is performed.

Here, in a case where the protrusion paths 54 protrude from the first injection plate 51 by the same length, a deviation may occur because a flow rate and a pressure of a gas are partially changed due to a process condition such as the kind of the processing process, the kind of a gas, and a temperature. In order to compensate for such a difference, in the substrate processing apparatus 1 according to a modified embodiment of the present inventive concept, the protrusion paths 54 may be implemented as follows.

Referring to FIGS. 10 to 14, a first protrusion path 541 disposed in a first region FA among the protrusion paths 54 and a second protrusion path 542 disposed in a second region SA differing from the first region FA among the protrusion paths 54 may protrude by different lengths. That is, each of the first protrusion path 541 and the second protrusion path 542 may be implemented to have different lengths which protrude toward the substrate S.

Therefore, in the substrate processing apparatus 1 according to a modified embodiment of the present inventive concept, in a case where a pressure difference and a flow rate difference of a gas between the first region FA and the second region SA occur due to a process condition or the like, the pressure difference and the flow rate difference of the gas occurring between the first region FA and the second region SA may be compensated for by using a difference between a length of the first protrusion path 541 and a length of the second protrusion path 542.

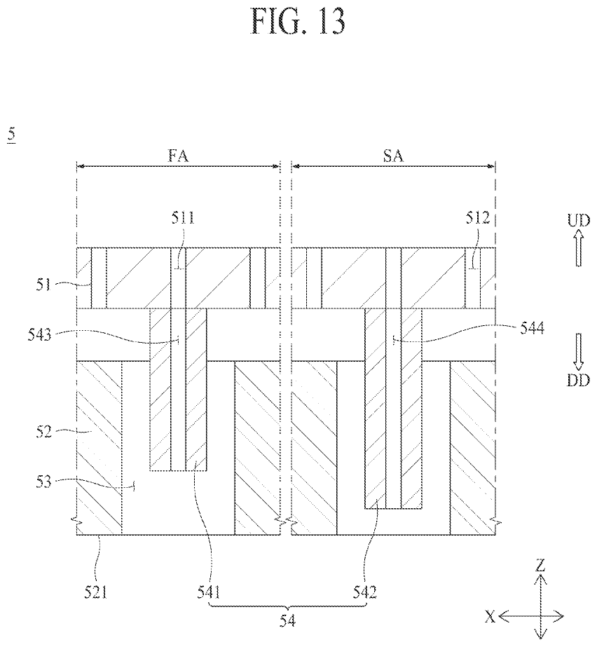

For example, when a length of the first protrusion path 541 is the same as that of the second protrusion path 542, in a case where a pressure and a flow rate of a gas injected into the second region SA is reduced compared to the first region FA due to a process condition or the like, a process environment may be implemented where a pressure and a flow rate of a gas injected into the second region SA increase more than the first region FA. To this end, as illustrated in FIG. 13, the second protrusion path 542 may protrude toward the substrate S by a longer length than the first protrusion path 541. Therefore, a pressure and a flow rate of a gas injected into the second region SA by using the second protrusion path may increase, and thus, a deviation of each of a pressure and a flow rate of a gas between the second region SA and the first region FA may decrease.

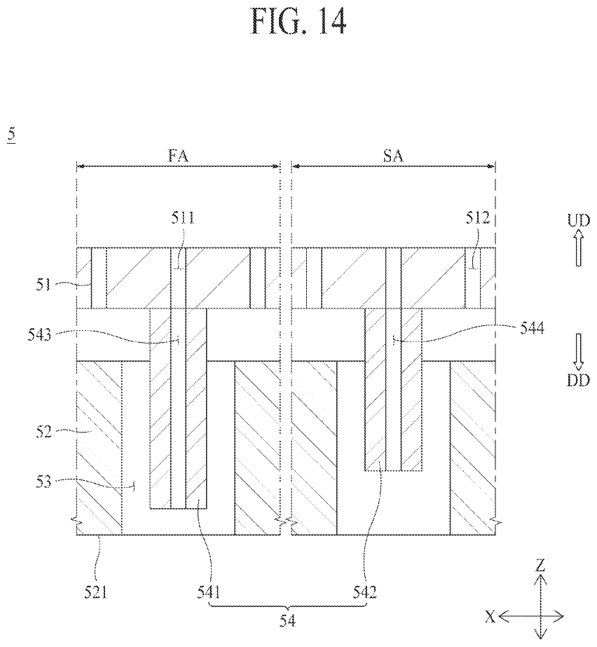

For example, when a length of the first protrusion path 541 is the same as that of the second protrusion path 542, in a case where a pressure and a flow rate of a gas injected into the first region FA is reduced compared to the second region SA due to a process condition or the like, a process environment may be implemented where the pressure and the flow rate of the gas injected into the first region FA increase more than the second region SA. To this end, as illustrated in FIG. 14, the first protrusion path 541 may protrude toward the substrate S by a longer length than the second protrusion path 542. Therefore, a pressure and a flow rate of a gas injected by using the first protrusion path 541 in the first region FA may increase, and thus, a deviation of each of a pressure and a flow rate of a gas between the first region FA and the second region SA may decrease.

As described above, the substrate processing apparatus 1 according to a modified embodiment of the present inventive concept is implemented to control a pressure and a flow rate of a gas for each region by using a difference between a length of the first protrusion path 541 and a length of the second protrusion path 542. Therefore, the substrate processing apparatus 1 according to a modified embodiment of the present inventive concept may enhance the uniformity of each of a pressure and a flow rate of a gas in one whole surface of the substrate S facing the electrode unit 4, thereby enhancing the quality of a substrate on which the processing process is completed.

The second region SA may be disposed outside the first region FA. In this case, as illustrated in FIG. 12, the second region SA may be disposed outside the first region FA to surround the first region FA. Although not shown, when each of the second region SA and the first region FA is a region where a pressure difference and a flow rate difference of a gas occurs due to a process condition or the like, the second region SA and the first region FA may be implemented as a type and arrangement which differ from the illustration of FIG. 12. Hereinabove, it has been described that lengths of the protrusion paths 54 differ in two regions FA and SA, but the present inventive concept is not limited thereto and the lengths of the protrusion paths 54 may be differently implemented in three or more regions. Also, in FIG. 12, it is illustrated that the first injection plate 51 has a tetragonal shape, but the present inventive concept is not limited thereto and the first injection plate 51 may be formed in various shapes such as a tetragonal or more-shaped polygonal shape and a circular shape.

Referring to FIGS. 13 and 14, the first protrusion path 541 and the second protrusion path 542 may be inserted into the injection hole 53 and may be disposed inward from the second injection plate 52. In this case, with respect to the vertical direction (the Z-axis direction), each of the first protrusion path 541 and the second protrusion path 542 may protrude toward the substrate S by a longer length than a length by which the first injection plate 51 is apart from the second injection plate 52.

One of the first protrusion path 541 and the second protrusion path 542 inserted into the injection hole 53 may be the same plane as the bottom surface 521 of the second injection plate 52. In this case, a bottom surface of the first protrusion path 541 or a bottom surface of the second protrusion path 542 may be disposed at the same height as the bottom surface 521 of the second injection plate 52. A bottom surface of a protrusion path, having a longer length, of the first protrusion path 541 and the second protrusion path 542 may be disposed at the same height as the bottom surface 521 of the second injection plate 52. A bottom surface of a protrusion path, having a shorter length, of the first protrusion path 541 and the second protrusion path 542 may be disposed at a higher height than the bottom surface 521 of the second injection plate 52, and thus, may be disposed inward from the second injection plate 52. Also, all of the first protrusion path 541 and the second protrusion path 542 inserted into the injection hole 53 may be the same plane as the bottom surface 521 of the second injection plate 52.

Referring to FIGS. 13 and 14, when the first protrusion path 541 and the second protrusion path 542 protrude by different lengths, the bottom surface 521 of the second injection plate 52 may be formed to be flat. That is, all of the bottom surface 521 of the second injection plate 52 may be disposed at the same height. Accordingly, in controlling a pressure and a flow rate of a gas for each region by using a difference between a length of the first protrusion path 541 and a length of the second protrusion path 542, the bottom surface 521 of the second injection plate 52 may be implemented not to be affected.

Referring to FIGS. 13 and 14, the first protrusion path 541 may include a first injection hole 543 for injecting the first gas. The first injection hole 543 may be formed to pass through the first protrusion path 541. The first injection hole 543 may be connected to a second connection hole 512 formed in the first injection plate 51. The second connection hole 512 may be formed to pass through the first injection plate 51. In this case, the first gas may be injected into a space disposed on the first injection plate 51, and then, may be injected toward the substrate supporting unit 3 through the second connection hole 512 and the first injection hole 543. The second connection hole 512 and the first connection hole 511 may be formed spatially apart from each other.

Referring to FIGS. 13 and 14, the second protrusion path 542 may include a second injection hole 544 for injecting the first gas. The second injection hole 544 may be formed to pass through the second protrusion path 542. The second injection hole 544 may be connected to the second connection hole 512 formed in the first injection plate 51. In this case, the first gas may be injected into a space disposed on the first injection plate 51, and then, may be injected toward the substrate supporting unit 3 through the second connection hole 512 and the second injection hole 544.

Moreover, a plurality of first protrusion paths 541 may be disposed in the first region FA. In this case, the first protrusion paths 541 may protrude toward the substrate S by the same length. A plurality of second protrusion paths 542 may be disposed in the second region SA. In this case, the second protrusion paths 542 may protrude toward the substrate S by the same length.

The present inventive concept described above are not limited to the above-described embodiments and the accompanying drawings and those skilled in the art will clearly appreciate that various modifications, deformations, and substitutions are possible without departing from the scope and spirit of the invention.

1. A substrate processing apparatus comprising:
a process chamber providing a reaction space for processing a substrate;
a substrate supporting unit supporting the substrate;
a first electrode installed in the process chamber, the first electrode being opposite to the substrate and including a plurality of protrusion electrodes protruding toward the substrate; and
a second electrode disposed under the first electrode, the second electrode including a plurality of openings into which the plurality of protrusion electrodes are inserted,
wherein a first protrusion electrode disposed in a first region and a second protrusion electrode disposed in a second region outside the first region among the protrusion electrodes protrude by different lengths.

2. The substrate processing apparatus of claim 1, wherein the first protrusion electrode protrudes toward the substrate by a longer length than the second protrusion electrode.

3. The substrate processing apparatus of claim 1, wherein the second protrusion electrode protrudes toward the substrate by a longer length than the first protrusion electrode.

4. The substrate processing apparatus of claim 1, wherein
the first protrusion electrode comprises a first injection hole injecting a first gas,
the second protrusion electrode comprises a second injection hole injecting a second gas, and
an area of the first injection hole differs from an area of the second injection hole.

5. The substrate processing apparatus of claim 1, wherein one of the first protrusion electrode and the second protrusion electrode inserted into the opening is the same plane as a bottom surface of the second electrode.

6. The substrate processing apparatus of claim 1, wherein a part of the second electrode in the first region and another part of the second electrode in the second region protrude toward the substrate by different lengths.

7. A substrate processing apparatus comprising:
a process chamber providing a reaction space for processing a substrate;
a substrate supporting unit supporting the substrate;
a first electrode installed in the process chamber, the first electrode being opposite to the substrate and including a plurality of protrusion electrodes protruding toward the substrate; and
a second electrode disposed under the first electrode, the second electrode including a plurality of openings into which the plurality of protrusion electrodes are inserted,
wherein a part of the second electrode in a first region and another part of the second electrode in a second region outside the first region in the second electrode are apart from the substrate supporting unit by different lengths.

8. The substrate processing apparatus of claim 7, wherein the part of the second electrode in the first region is apart from the substrate supporting unit by a longer distance than the another part of the second electrode in the second region.

9. The substrate processing apparatus of claim 7, wherein the another part of the second electrode in the second region is apart from the substrate supporting unit by a longer distance than the part of the second electrode in the first region.

10. The substrate processing apparatus of claim 7, wherein
a first protrusion electrode disposed in the first region among the protrusion electrodes comprises a first injection hole injecting a first gas,
a second protrusion electrode disposed in the second region among the protrusion electrodes comprises a second injection hole injecting a second gas, and
an area of the first injection hole differs from an area of the second injection hole.

11. The substrate processing apparatus of claim 4, wherein an area of the first injection hole is formed to be greater than an area of the second injection hole.

12. The substrate processing apparatus of claim 4, wherein an area of the second injection hole is formed to be greater than an area of the first injection hole.

13. The substrate processing apparatus of claim 4, wherein the area of the first injection hole and the area of the second injection hole are horizontal cross-sectional areas.

14. The substrate processing apparatus of claim 10, wherein at least one of the first protrusion electrode and the second protrusion electrode inserted into the opening is the same plane as a bottom surface of the second electrode.

15. The substrate processing apparatus of claim 7, wherein a first protrusion electrode disposed in the first region and a second protrusion electrode disposed in the second region among the protrusion electrodes protrude by different lengths.

16. The substrate processing apparatus of claim 10, wherein a first protrusion electrode disposed in the first region and a second protrusion electrode disposed in the second region among the protrusion electrodes protrude by the same length.

17. A substrate processing apparatus comprising:
a process chamber providing a reaction space for processing a substrate;
a substrate supporting unit supporting the substrate;
a first injection plate installed in the process chamber, the first injection plate being opposite to the substrate and including a plurality of protrusion paths protruding toward the substrate and injecting a first gas; and
a second injection plate disposed under the first injection plate, the second injection plate including a plurality of injection holes into which the protrusion paths are inserted and through which a second gas is injected,
wherein a first protrusion path disposed in a first region and a second protrusion path disposed in a second region outside the first region among the protrusion paths protrude by different lengths.

18. The substrate processing apparatus of claim 17, wherein the first protrusion path protrudes toward the substrate by a longer length than the second protrusion path.

19. The substrate processing apparatus of claim 17, wherein the second protrusion path protrudes toward the substrate by a longer length than the first protrusion path.

20. The substrate processing apparatus of claim 10, wherein a first protrusion electrode disposed in the first region and a second protrusion electrode disposed in the second region among the protrusion electrodes protrude by different lengths.
